(19) United States
(12) Patent Application Publication
(10) Pub. No.: US 2017/0336472 A1
(43) Pub. Date: Nov. 23, 2017

(54) CONDITIONAL ACCESS CHIP, BUILT-IN SELF-TEST CIRCUIT AND TEST METHOD THEREOF

(71) Applicant: MStar Semiconductor, Inc., Hsinchu Hsien (TW)

(72) Inventors: SHANG-TA TSAI, Hsinchu County (TW); PEI-EN WENG, Hsinchu County (TW); TSUNG-TA LU, Hsinchu County (TW)

(21) Appl. No.: 15/398,847

(22) Filed: Jan. 5, 2017

(30) Foreign Application Priority Data
May 19, 2016 (TW) 105115415

(51) Int. Cl. G01R 31/3177; G01R 31/317

(52) U.S. Cl. CPC G01R 31/3177; G01R 31/31703; G01R 31/31725

(57) ABSTRACT

A self-test built in a conditional access chip is provided. The conditional access chip decrypts video data by using a plurality of logic units. The self-test circuit includes: a storage circuit, storing test data and comparison data; and a control circuit, coupled to the logic units, controlling the logic units to receive a clock to perform a test, reading the test data from the storage circuit, inputting the test data to a scan chain formed by the logic units according to the clock, and comparing output data of the scan chain with the comparison data to obtain a test result.

### This application claims the benefit of Taiwan application Serial No. 105115415, filed May 19, 2016, the subject matter of which is incorporated herein by reference.

### BACKGROUND OF THE INVENTION

### Field of the Invention

The invention relates in general to a conditional access chip, and more particularly to a test circuit and a test method applied in a conditional access chip.

### Description of the Related Art

Conditional access is frequently used to protect digital contents, and decrypts protected data by using a key stored in a function chip. In general, an active shield layer is formed at an uppermost metal layer of a semiconductor structure used for manufacturing a conditional access chip. When the chip is invaded (e.g., attacked by a focus ion beam (FIB)), the active shield layer may likely be sabotaged. Thus, the chip may verify whether the key is secure through checking a state of the active shield layer.

However, being formed at a surface of the chip, the active shield layer may be easily known to and eluded by one of questionable intentions. Further, the attack may come from the side of the chip instead of from the surface. These possibilities may cause theft of the key inside the chip, although the active shield layer may seem to kept intact. Therefore, there is a need for a solution that ensures data security of a conditional access chip.

### SUMMARY OF THE INVENTION

The invention is directed to a self-test circuit and test method built in a conditional access chip to increase the security of the conditional access chip.

The present invention discloses a self-test circuit built in a conditional access chip. The conditional access chip decrypts video data by using a plurality of logic units. The self-test circuit includes: a storage circuit, storing test data and comparison data; and a control circuit, coupled to the logic units, controlling the logic units to receive a clock to perform a test, reading the test data from the storage circuit, inputting the test data into a scan chain formed by the logic units according to the clock; and comparing output data of the scan chain with the comparison data to obtain a test result.

The present invention further discloses a self-test for a conditional access chip. The conditional access chip decrypts video data by using a plurality of logic units, and includes a storage circuit storing test data and comparison data. The self-test method include: controlling the logic units to receive a clock to perform a test; reading the test data from the storage circuit; inputting the test data into a scan chain formed by the logic units; and comparing output data of the scan chain with the comparison data to obtain a test result.

The conditional access chip, the built-in self test circuit and test method of the present invention directly test the logic units and logic circuits in the chip and enhance test security by storing the test data in the chip in advance, and are thus capable of reliably learning whether the chip is sabotaged. Compared to the prior art, the present invention enhances the security of a conditional access chip and can be easily implemented.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a partial circuit diagram of a conditional access chip according to an embodiment of the present invention;

FIG. 2 is a flowchart of a self-test method for a conditional access chip according to an embodiment of the present invention;

FIG. 3 is a detailed process of scanning a scan chain of step S250 in FIG. 2;

FIG. 4 is a schematic diagram of a connection between two logic units in a scan chain according to an embodiment of the present invention; and

FIG. 5 is a schematic diagram of one of the logic units in the scan chain according to an embodiment of the present invention.

### DETAILED DESCRIPTION OF THE INVENTION

The disclosure includes a conventional access chip, a built-in self-test circuit and a test method. The device and method may be applied to a receiver of a digital television or a set-top box (STB). In possible implementation, one person skilled in the art can choose equivalent elements or steps to realize the present invention based on the disclosure. That is, the implementation of the present invention is not limited to the following non-limiting embodiments.

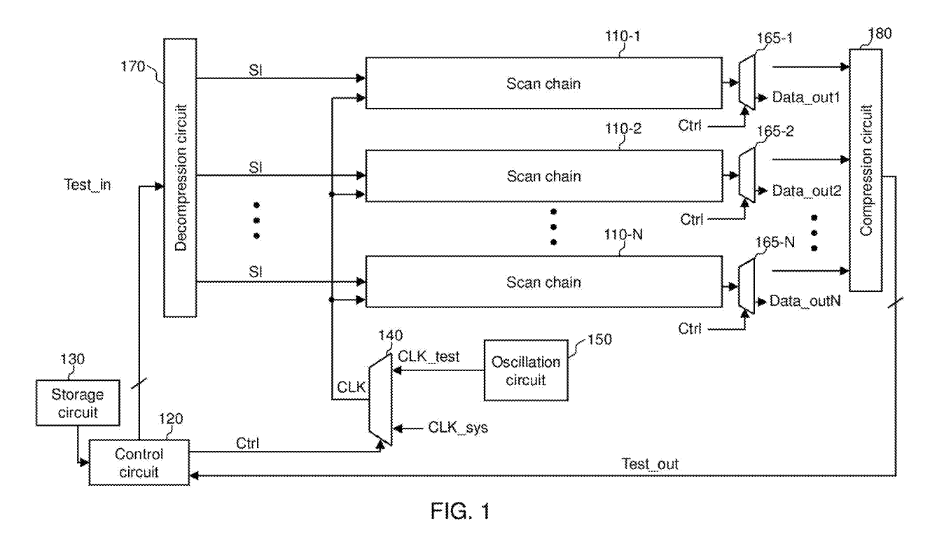

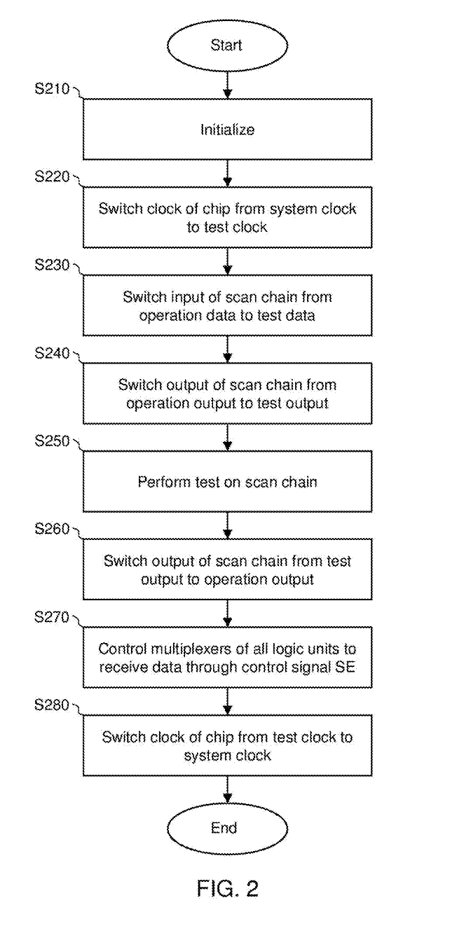

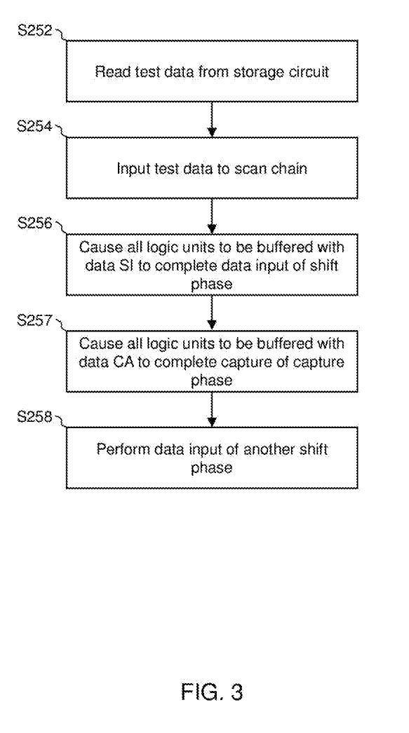

The conditional access chip of the present invention is operable in a work mode and a test mode. In the work mode, the conditional access chip performs a normal function (e.g., decrypting video data when the chip is applied to a digital television); in the test mode, logic units in function modules in the conditional access chip are connected in series into scan chains, and test data is inputted into the scan chains to test whether the chip is sabotaged. The test data of the present invention and the corresponding test result are stored in the chip. FIG. 1 shows a partial circuit diagram of a conditional access chip according to an embodiment of the present invention. Except the logic units that form the scan chains 110-1 to 110-N, the remaining circuits in FIG. 1 may be regarded as a built-in self-test circuit of the conditional access chip. A storage circuit 130 stores the above test data and corresponding test result. A control circuit 120, coupled to the storage circuit 130, reads test data Test_in and a corresponding test result, inputs the test data Test_in into the scan chains 110-1 to 110-N (where N is a positive integer), and compares output result Test_out of the scan chains 110 with the corresponding test result to determine whether the chip is sabotaged. In one embodiment, for example, the control circuit 120 may be a microcontroller unit or a microprocessor, and achieves its function through a process or algorithm in FIG. 2 and FIG. 3. The storage circuit 130 may be a read-only memory built-in the microcontroller unit or the microprocessor.

FIG. 2 shows a flowchart of a self-test method for a conditional access chip according to an embodiment of the present invention. Operation details are given with reference to both FIG. 1 and FIG. 2. At the beginning of the test, system initialization is first performed (step S210), e.g., resetting the logic units of the scan chains, and resetting a counter and registers of the control circuit. After the initialization, the control circuit 120 switches a clock according to which the chip operates from a system clock to a test clock (step S220); i.e., switching the chip from the work mode to the test mode. More specifically, when the chip performs a normal function in the work mode, its function modules may perform respective tasks according to different clocks, which may be generated through an PLL by using the system clock of the chip, for example. In the test mode, all of the logic units operate according to the same test clock. As shown in FIG. 1, by using a control signal Ctrl, the control circuit 120 selects a system clock CLK_system or a test clock CLK_test as an operation clock CLK of the scan chains 110-1 to 110N. In this embodiment, when the control signal Ctrl is switched from disable to enable (or vice versa), it means that the chip enters the test mode from the work mode. At this point, a multiplexer 140 switches the operation clock CLK from the system clock CLK_sys to the test clock CLK_test. In one embodiment, the test clock CLK_test is generated by an oscillation circuit 150 built in the chip. The above design provides a benefit of enhanced security and reliability for test. If the test clock is provided from outside the chip, the test clock may be easily modified to cause a manipulated test result.

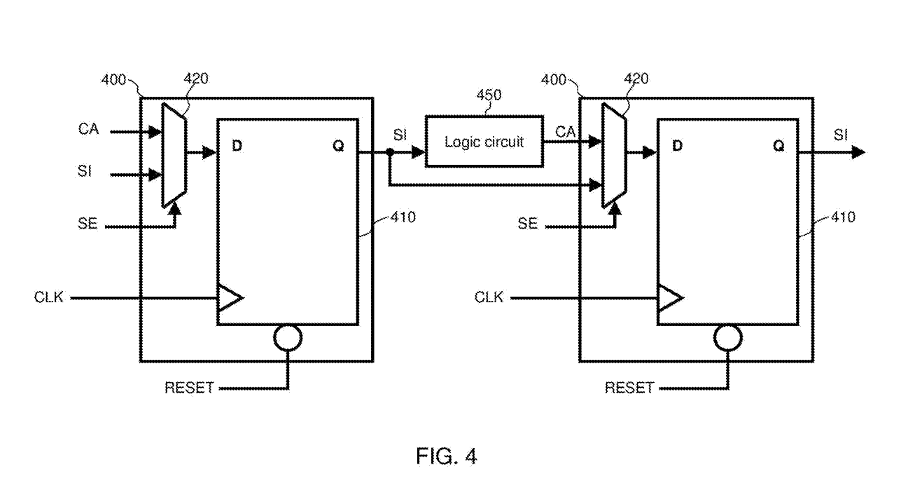

FIG. 4 shows a schematic diagram of a connection between two logic units in a scan chain according to an embodiment of the present invention. In addition to logic units 400 connected in series, the scan chain further includes a logic circuit 450 between the two consecutive logic units 400. The logic circuit 450 refers a circuit that provides an input signal to one of the logic units 400 during a normal operation of the conditional access chip. Each of the logic units 400 includes a flip-flop 410 and a multiplexer 420. The flip-flop 410 operates according to the operation clock CLK, and resets data stored therein according to a signal RESET. There are two sources of data for an input end D—data SI and data CA. The multiplexer 420 determines which type of data is to be inputted into the flip-flop 410 according to a control signal SE (not shown in FIG. 1), which is generated by the control unit. The data SI is data that is directly outputted by a previous-stage logic unit 400 in the scan chain, and is in fact test data Test_in or data generated according to the test data Test_in. The data CA is output of the logic circuit 450. An output end Q of the flip-flop 410 is coupled to the next-stage logic circuit 450 and the multiplexer 420 of the next-stage logic unit 400. Taking the scan chain 110-1 for example, when the control signal SE controls the multiplexers 420 of all of the logic units 400 to switch to receive the data SI (step S230), the data SI may be sequentially transmitted to each of the logic units 400 in the scan chain 110-1. Similarly, operations of the scan chains 110-2 to 110-N are identical to those of the scan chain 110-1.

Again referring to FIG. 1, the output ends of the scan chains 110-1 to 110-N switch respective work outputs Data_out1 to Data_outN to respective test outputs through controlling the multiplexers 165-1 to 165-N (step S240), so as to allow the subsequent control circuit 120 to compare with the corresponding test results after receiving the integrated test result Test_out. In step S250, the control circuit 120 performs a scan chain test according to a cycle of the clock_test. The scan chain test of the present invention includes a shift phase and a capture phase of the scan chain, with associated test details to be described shortly. After the test is complete, the control circuit 120 causes the control signal Ctrl to change from an enabled state to a disabled state, and so the multiplexers 165-1 to 165-N switch the outputs of the scan chains 110-1 to 110-N from respective test outputs to respective work outputs (step S260), and the multiplexer 140 switch the clock of the scan chains 110-1 to 110-N from the test clock CLK_test back to the system clock CLK_sys (step S280). Further, through the control signal SE, the control circuit 120 controls the multiplexers 420 of all of the logic units 400 to receive the data CA (step S270). Thus, the test for the chip is complete, and the chip may return to the normal operation state, in which the function modules perform respective original functions.

In one embodiment, to save the storage space of the storage circuit 130 and to reduce the pin count between the control circuit 120 and the scan chains 110-1 to 110-N, the test data Test_in is stored in a compressed from in the storage circuit 130, and is decompressed by a decompression circuit 170 before being inputted into the scan chains 110-1 to 110-N. Further, all test outputs are compressed into the test result Test_out by a compression circuit 180. In one embodiment, the decompression circuit 170 and the compression circuit 180 are implemented by hardware, and the decompression circuit 170 has an output pin count equal to the number of the scan chains 110-1 to 110-N and an input pin count smaller than the number of the scan chains 110-1 to 110-N. Similarly, the compression circuit 180 has an input pin count equal to the number of the scan chains 110-1 to 110-N, and an output pin count smaller than the number of the scan chains 110-1 to 110-N. For example but not limited to, the decompression circuit 170 and the compression circuit 180 may be implemented by DFTMAX compression/decompression circuits.

FIG. 3 shows a detailed process of the scan chain test of step S250 in FIG. 2. At the beginning of the scan chain test, the control circuit 120 first reads test data Test_in from the storage circuit 130 (step S252). The test data Test_in read out may be partially or entirely stored in a buffer (not shown) in the control circuit 120 to be readily and promptly provided to the scan chains 110-1 to 110-N during the test process. The data SI is then generated according to the test data Test_in and inputted into the scan chains (step S254). It should be noted that, the test data of the present invention may also be stored in a non-compressed form in the storage circuit 130. In such situation, the decompression circuit 170 and the compression circuit 180 are not needed, and the test data Test_in may be directly used as the data SI to be inputted in the scan chains. Referring to step S220 in FIG. 2, as the operation clock CLK is already switched from the system clock CLK_sys to the test clock CLK_test in step S220, the data SI is transmitted forward at a speed of one logic unit per test clock cycle in the scan chains 110-1 to 110-N towards the output ends of the scan chains 110-1 to 110-N.

As previously mentioned, the scan chain test may be divided into a shift phase and a capture phase. The shift phase is used to fill all of the flip-flops 410 by the data SI, and the capture phase is for testing whether the operations of all of the logic units and the logic circuits 450 between the logic units are correct. In one embodiment, the control signal SE is effective only when the control signal Ctrl is enabled. That is, only when the control signal Ctrl is enabled, it then can control the current scan chain test to be in the shift phase or the capture phase. In another embodiment, the control signal Ctrl may be directly used as the control signal SE. In the description below, one scan line 110-1 is taken as an example for explaining the test in the shift phase and the capture phase. Assuming that the length of the scan chain 110-1 is 400 logic units and the length of the data SI is 400 bits, the data SI is sequentially transmitted forward among these logic units in 400 consecutive cycles of the test clock CLK_test, hence completing the data input of the shift phase (step S256). In brief, the shift phase is for causing all of the flip-flops 410 on the scan chain 110-1 to be buffered with the data SI. Next, the control signal SE controls all of the multiplexers 420 on the scan chain 110-1 to select the data CA, and to perform the input of one cycle of the test clock CLK_test. At this point, a new value is obtained as all of the flip-flops 410 on the scan chain 110 receive respective data CA to complete the capture of the capture phase (step S257). Next, the control signal SE controls all of the multiplexers 420 on the scan chain 110-1 to again select the data SI, and to again enter the shift phase. As such, in the subsequent 400 consecutive cycles of the test clock CLK_test, the data SI is again inputted the scan chain 110-1 until all of the logic units are buffered with the data SI. Thus, the new values obtained by all of the flip-flops 410 in step S257 may be sequentially transported out of the scan chain 110-1, and these new values are the test result Test_out, hence completing the data input of another shift phase (step S258). It should be noted that, the second shift phase is for allowing the output end of the scan chain to obtain the new values obtained by all of the multiplexers 420 on the scan chain 110-1, and the present invention utilizes these new values to determine whether all of the multiplexers 420 and the associated logic circuits on the scan chain 110 are functional. In another embodiment, all of the multiplexers 420 on the scan chain 110-1 may perform the input of more than one cycle of the test clock CLK_test after selecting the data CA. In yet another embodiment, through repeatedly operating the shift phase and the capture phase, the self-test circuit of the present invention may successively perform the test on different sets of data SI.

To save the number of times of comparison, the control circuit 120 may first compute the test result Test_out and then compare with a corresponding test result, instead of checking the test result Test_out in every cycle of the test clock. There are various ways to conduct the computation, for example but not limited to, a cyclic redundancy check (CRC). The control circuit 120 continues performing a CRC operation on the newly generated test result and the existing test result, and uses the latest operation result as the test result Test_out that is then compared with the corresponding test result.

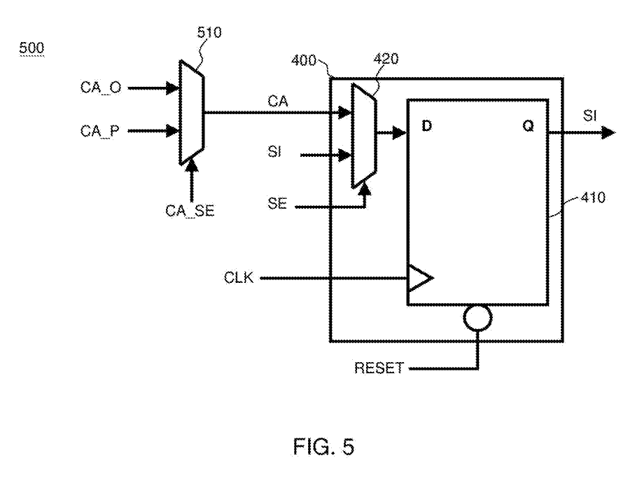

FIG. 5 shows a schematic diagram of another logic unit 500 in a scan chain according to an embodiment of the present invention. In addition to the logic unit 400, the logic unit 500 further includes a multiplexer 510. The multiplexer 510 has a first end that receives normal logic signal CA_O, which is an output that a logic circuit corresponding to the logic unit 500 outputs in a normal operation. The multiplexer 510 further has a second receiving end that receives predetermined logic signal CA_P, which is a predetermined logic signal. Because many logic units in the entire conditional access chip are associated with other circuits outside the chip, to effectively block other circuits outside the chip, the logic unit 500 receives the predetermined logic signal CA_P according to a control signal CA_SE in the self-test process. Thus, the predetermined logic signal CA_P may be provided as the data CA in the capture phase to prevent interference from outside the chip. When the test ends, the logic unit 500 receives the normal logic signal CA_O according to the control signal CA_SE to restore to the normal operation.

In conclusion, in the present invention, the logic units in the chip are configured into scan chains, which are directly tested. In the event of alterations or theft of the key in the chip, whether the chip is sabotaged may be learned through the test result, and the chip may then be caused to stop operate normally. Instead of being inputted from outside the chip, the test data used in the test process of the present invention is stored in the chip in advance, hence ensuring test security. Further, by using the oscillation circuit 150 additionally provided in the chip as the source of test clock, the closed property of the test performed on the system may be further increased to prevent interference during the test process. Further, in the test process of the present invention, rather than checking the test result in every cycle of the test clock, the test result is first computed and then compared with the predetermined corresponding data, which helps reducing the number of times of comparison to further enhance test efficiency. The decompression circuit 170 and the compression circuit 180 located between the scan chains and the control circuit 120 are beneficial for reducing the storage space of the storage circuit 130 as well as reducing the pin count of the control circuit 120.

One person skilled in the art may understand implementation details and variations of the method in FIG. 2 and FIG. 3 based on the disclosure of the device in FIG. 1 and FIG. 4. While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A self-test circuit built in a conditional access chip, the conditional access chip decrypting video data by using a plurality of logic units, the self-test circuit comprising:
a storage circuit, storing test data and comparison data; and
a control circuit, coupled to the logic units, controlling the logic units to receive a clock to perform a test, reading the test data from the storage circuit, inputting the test data into a scan chain formed by the logic units according to the clock, and comparing output data of the scan chain with the comparison data to obtain a test result.

2. The self-test circuit according to claim 1, wherein the clock is a first clock, the control circuit controls the logic units to receive a second clock when the test ends, and the second clock is not equal to the first clock.

3. The self-test circuit according to claim 1, further comprising:
an oscillation circuit, coupled to the control circuit and the logic units, generating the clock.

4. The self-test circuit according to claim 1, wherein the scan chain outputs a plurality of test results respectively corresponding to a plurality of consecutive cycles of the clock, and the output data is one operation result of the test results.

5. The self-test circuit according to claim 1, wherein the test comprises a shift phase and a capture phase, and one of the logic units comprises:
a flip-flop, comprising:
a first input end;
a second input end, receiving the clock; and
a first output end, coupled to a next logic unit of the logic unit; and
a multiplexer, comprising:
a third input end, receiving the test data outputted by a previous logic unit of the logic unit;
a fourth input end, receiving normal data; and
a second output end, outputting the test data to the first input end in the shift phase, and outputting the normal data to the first input end in the capture phase.

6. The self-test circuit according to claim 5, wherein the normal data is provided by a logic circuit.

7. The self-test circuit according to claim 5, wherein the multiplexer is a first multiplexer, the logic unit further comprises:
a second multiplexer, comprising:
a fifth input end, receiving security data;
a sixth input end, receiving non-security data; and
a third output end, outputting the security data as the normal data in the capture phase, and outputting the non-security data as the normal data when the test ends.

8. The self-test circuit according to claim 1, the logic units forming a plurality of scan chains, the self-test circuit further comprising:
a decompression circuit, compressing the test data, comprising at least one decompression circuit input end and a plurality of decompression circuit output ends, the at least one decompression circuit input end coupled to the control circuit, the decompression circuit output ends coupled to the scan chains; wherein, the number of the decompression circuit input end is smaller than the number of the decompression circuit output ends.

9. The self-test circuit according to claim 1, the logic units forming a plurality of scan chains, the self-test circuit further comprising:
a compression circuit, compressing the output data of the scan chains, comprising at least one compression circuit output end and a plurality of compression circuit input ends, the at least one compression circuit output end coupled to the control circuit, the compression circuit input ends coupled to the scan chains; wherein, the number of the compression circuit output end is smaller than the number of the compression circuit input ends.

10. A self-test method for a conditional access chip, the conditional access chip decrypting video data by using a plurality of logic units and comprising a storage circuit storing test data and comparison data, the self-test circuit comprising:
controlling the logic units to receive a clock to perform a test;
reading the test data from the storage circuit;
inputting the test data into a scan chain formed by the logic units according to the clock; and
comparing output data of the scan chain with the comparison data to obtain a test result.

11. The self-test method according to claim 10, the clock being a first clock, the self-test method further comprising:
when the test ends, controlling the logic units to receive a second clock;
wherein, the second clock is not equal to the first clock.

12. The self-test method according to claim 10, wherein the conditional access chip further comprises an oscillation circuit that generates the clock, and refers to the clock but not an external clock of the conditional access chip when the test is performed.

13. The self-test method according to claim 10, further comprising:
outputting a plurality of test results respectively corresponding to a plurality of consecutive cycles of the clock by the scan chain;
wherein, the output data is an operation result of the test results.

14. The self-test method according to claim 10, wherein the test comprises a shift phase and a capture phase, and one of the logic units comprises:
a flip-flop, comprising:
a first input end;
a second input end, receiving the clock; and
a first output end, coupled to a next logic unit of the logic unit; and
a multiplexer, comprising:
a third input end, receiving the test data outputted by a previous logic unit of the logic unit;
a fourth input end, receiving normal data; and
a second output end, outputting the test data to the first input end in the shift phase, and outputting the normal data to the first input end in the capture phase.

15. The self-test method according to claim 14, wherein the normal data is provided by a logic circuit.

16. The self-test method according to claim 14, wherein the multiplexer is a first multiplexer, the logic unit further comprises:
a second multiplexer, comprising:
a fifth input end, receiving security data;
a sixth input end, receiving non-security data; and
a third output end, outputting the security data as the normal data in the capture phase, and outputting the non-security data as the normal data when the test ends.

17. The self-test method according to claim 10, the logic units forming a plurality of scan chains, the test data being compressed data, the self-test method further comprising:
decompressing the test data before inputting the test data into the scan chains.

18. The self-test method according to claim 10, the logic units forming a plurality of scan chains, the self-test method further comprising:
compressing the output data of the scan chains before comparing the output data with the comparison data.
